(19) United States
(12) Patent Application Publication
(10) Pub. No.: US 2023/0389354 A1
(43) Pub. Date: Nov. 30, 2023

(54) METHOD OF MANUFACTURING DISPLAY DEVICE

(71) Applicant: Samsung Display Co., Ltd., Yongin-si (KR)

(72) Inventor: Dongha Lee, Yongin-si (KR)

(73) Assignee: Samsung Display Co., Ltd., Yongin-si (KR)

(21) Appl. No.: 18/121,070

(22) Filed: Mar. 14, 2023

(30) Foreign Application Priority Data
May 27, 2022 (KR) 10-2022-0065287

(51) Int. Cl. H10K 59/12; H10K 71/13; H10K 59/122; H10K 59/35; H10K 71/40

(52) U.S. Cl. CPC H10K 59/1201; H10K 71/135; H10K 59/122; H10K 59/352; H10K 71/40

(57) ABSTRACT

A method of manufacturing a display device, includes preparing a substrate, forming a plurality of pixel electrodes on the substrate, forming a pixel-defining layer covering edge portions of the plurality of pixel electrodes and defining a plurality of exposed upper surfaces of the plurality of pixel electrodes, and forming an emission layer on the plurality of exposed upper surfaces of the plurality of pixel electrodes. The forming of the emission layer includes forming an emission layer by ejecting ink onto the plurality of exposed upper surfaces in an order from an exposed upper surface having a largest area to an exposed upper surface having a smallest area.

### CROSS-REFERENCE TO RELATED APPLICATION(S)

This application claims priority to and benefits of Korean Patent Application No. 10-2022-0065287 under 35 U.S.C. § 119, filed on May 27, 2022, in the Korean Intellectual Property Office (KIPO), the entire contents of which are incorporated herein by reference.

### BACKGROUND

### 1. Technical Field

One or more embodiments relates to a method of manufacturing a display device that is capable of displaying high-quality images.

### 2. Description of the Related Art

With the progress of the information society, demands for display devices for displaying images have increased in various forms. Display devices have been making rapid changes to flat panel display (FPD) devices, which are thin, lightweight, and large-sized to replace cathode ray tubes (CRT) which are large in volume. Examples of the FPD devices include a liquid crystal display (LCD) device, a plasma display panel (PDP), an organic light-emitting display (OLED) device, and an electrophoretic display (EPD) device.

Among the display devices, the OLED devices may include, as a display element, an organic light-emitting diode which includes an opposite electrode, a pixel electrode, and an emission layer. By applying a voltage to the opposite electrode and the pixel electrode of the organic light-emitting diode, visible light rays may be emitted from the emission layer. The emission layer of the organic light-emitting diode may be formed by ejecting, onto the pixel electrode, ink including an organic material.

### SUMMARY

One or more embodiments provide a method of manufacturing a display device, in which ink is ejected onto a pixel electrode in the order from a relatively large area to a relatively small area of the pixel electrode, thereby minimizing an amount of naturally dried ink and thus preventing product defects.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a method of manufacturing a display device, may include preparing a substrate, forming a plurality of pixel electrodes on the substrate, forming a pixel-defining layer covering edge portions of the plurality of pixel electrodes and defining a plurality of exposed upper surfaces of the plurality of pixel electrodes, and forming an emission layer on the plurality of pixel electrodes, wherein the forming of the emission layer may include forming the emission layer by ejecting ink onto the plurality of exposed upper surfaces in an order from an exposed upper surface having a largest area to an exposed upper surface having a smallest area.

In an embodiment, the plurality of pixel electrodes may include a 1-1th pixel electrode disposed in a 1-1th pixel, a 2-1th pixel electrode disposed in a 2-1th pixel, and a 3-1th pixel electrode disposed in a 3-1th pixel, and the 1-1th pixel, the 2-1th pixel, and the 3-1th pixel may be configured to emit light of different wavelength bands from each other.

In an embodiment, the 1-1th pixel may be configured to emit red light, the 2-1th pixel may be configured to emit green light, and the 3-1th pixel may be configured to emit blue light.

In an embodiment, the plurality of exposed upper surfaces may include a 1-1th exposed upper surface disposed on the 1-1th pixel electrode, a 2-1th exposed upper surface disposed on the 2-1th pixel electrode, and a 3-1th exposed upper surface disposed on the 3-1th pixel electrode, and an area of the 1-1th exposed upper surface may be different from an area of the 2-1th exposed upper surface or an area of the 3-1th exposed upper surface.

In an embodiment, the area of the 1-1th exposed upper surface may be larger than the area of the 2-1th exposed upper surface and the area of the 3-1th exposed upper surface.

In an embodiment, the area of the 2-1th exposed upper surface may be larger than the area of the 1-1th exposed upper surface and the area of the 3-1th exposed upper surface.

In an embodiment, the area of the 3-1th exposed upper surface may be larger than the area of the 1-1th exposed upper surface and the area of the 2-1th exposed upper surface.

In an embodiment, the forming of the emission layer may include forming the emission layer including an upper portion of the emission layer that is flat at a center portion of each of the plurality of exposed upper surfaces.

In an embodiment, the method may further include baking the pixel-defining layer after the forming of the pixel-defining layer.

In an embodiment, an upper surface of a side surface of the pixel-defining layer may have liquid repellency.

In an embodiment, the method may further include forming an opposite electrode on the emission layer.

In an embodiment, the opposite electrode may cover the emission layer and the pixel-defining layer.

According to one or more embodiments, a method of manufacturing a display device, may include preparing a substrate, forming, on the substrate, a plurality of pixel electrodes disposed in a plurality of pixels emitting light of a same wavelength band, forming a pixel-defining layer covering edge portions of the plurality of pixel electrodes and defining a plurality of exposed upper surfaces of the plurality of pixel electrodes, the plurality of exposed upper surfaces having different areas from each other, and forming an emission layer on the plurality of exposed upper surfaces of the plurality of pixel electrodes, wherein the forming of the emission layer may include forming the emission layer by ejecting ink onto the plurality of exposed upper surfaces in the order from an exposed upper surface having a largest area to an exposed upper surface having a smallest area.

In an embodiment, the plurality of pixel electrodes may include a 1-1th pixel electrode disposed in a 1-1th pixel and a 1-2th pixel electrode disposed in a 1-2th pixel, and a 1-1th exposed upper surface on the 1-1th pixel electrode may be larger than a 1-2th exposed upper surface on the 1-2th pixel electrode.

In an embodiment, the plurality of pixel electrodes may further include a 1-3th pixel electrode disposed in a 1-3th pixel, and the 1-2th exposed upper surface may be larger than a 1-3th exposed upper surface on the 1-3th pixel electrode.

In an embodiment, areas of the plurality of exposed upper surfaces may include an area of the 1-1th exposed upper surface, an area of the 1-2th exposed upper surface, and an area of the 1-3th exposed upper surface, which are randomly arranged.

In an embodiment, the plurality of pixels emitting light of a same wavelength band may be configured to emit one of red light, green light, and blue light.

In an embodiment, the method may further include baking the pixel-defining layer after the forming of the pixel-defining layer.

In an embodiment, an upper surface of a side surface of the pixel-defining layer may have liquid repellency.

In an embodiment, the method may further include forming an opposite electrode on the emission layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of a display device according to an embodiment;

FIGS. 2 and 3 are partial schematic plan views of a display device, which may appear in a method of manufacturing a display device, according to embodiments;

FIG. 4 is a flowchart of a method of manufacturing a display device, according to an embodiment; and

FIGS. 5 to 11 are schematic cross-sectional views illustrating, in sequence, a method of manufacturing a display device.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

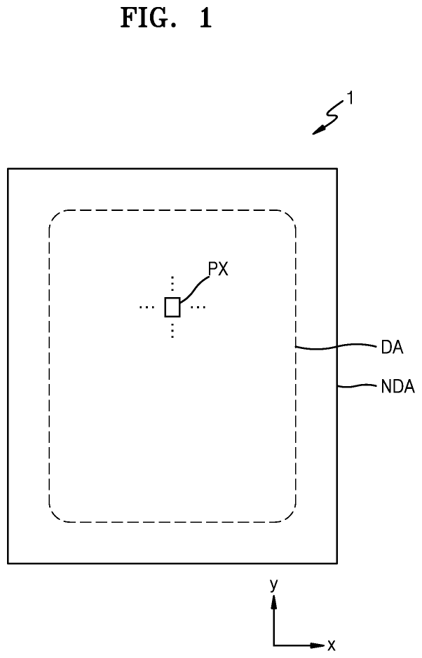

FIG. 1 is a schematic view of a display device according to an embodiment. Referring to FIG. 1, a display device 1 may include a display area DA and a peripheral area NDA of the display area DA. The display area DA may display a certain image by using light emitted from pixels PX. The pixels PX may each include a display element emitting light (for example, red light, green light, or blue light).

The peripheral area NDA may be an area where the pixels PX are not disposed and various wires and/or drivers, which transmit an electrical signal to be applied to the display area DA, are disposed. For example, the peripheral area NDA may be arranged adjacent to the display area DA and surround (e.g., entirely surround) the display area DA. In an embodiment, the display area DA may have an elongated rectangular shape extending in a ±Y-direction. In another example, the display area DA may have a polygonal shape such as a rectangular shape elongated in a ±X-direction or a square shape, or an elliptical or circular shape.

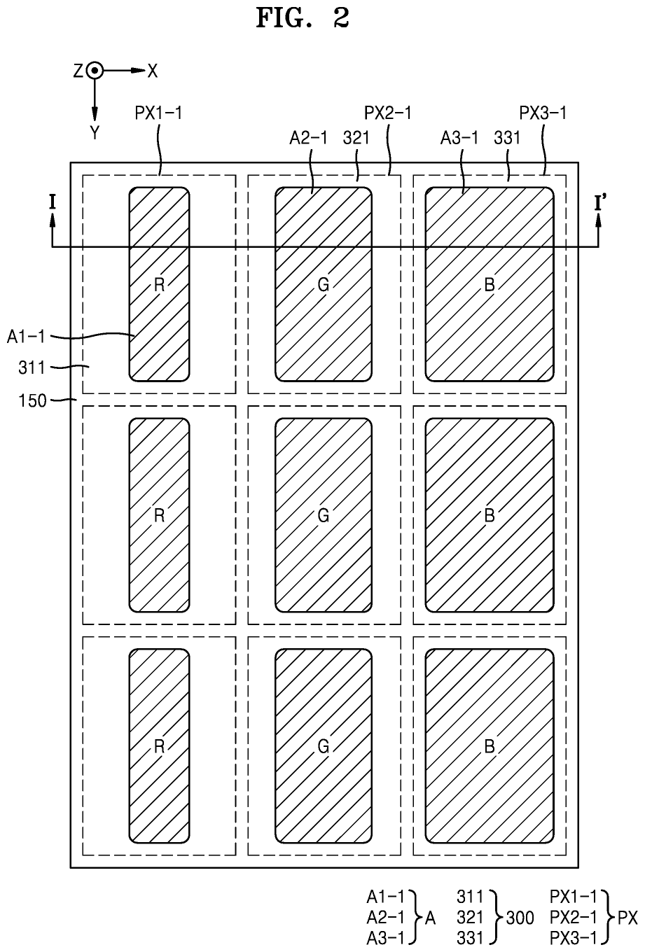

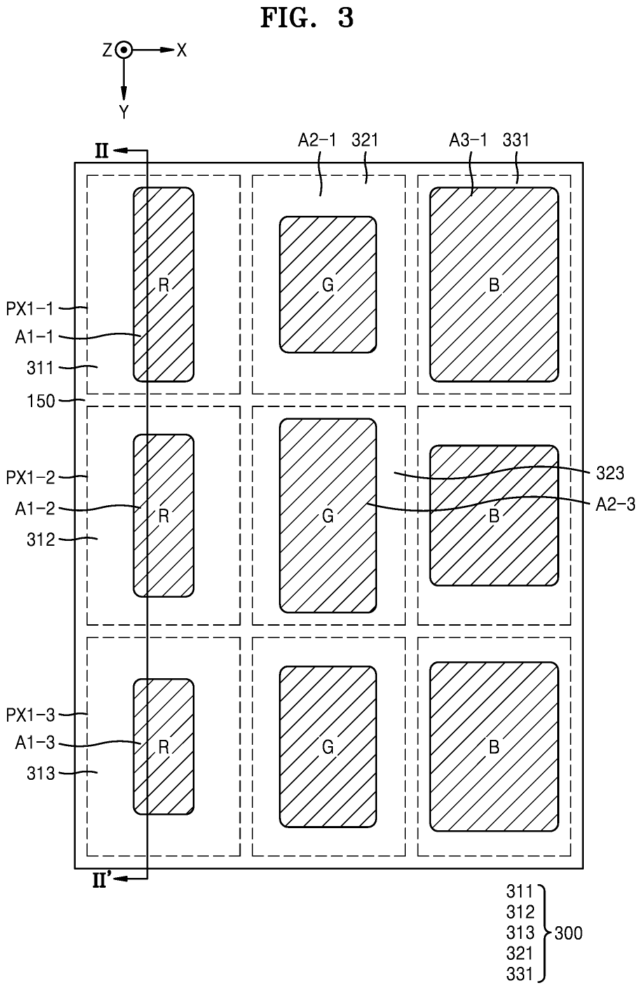

FIGS. 2 and 3 are partial schematic plan views of a display device 1 illustrated in a method of manufacturing a display device 1 and illustrate a pixel structure that may be applied to a display device according to an embodiment.

Referring to FIG. 2, a pixel PX may include a 1-1th pixel PX1-1, a 2-1th pixel PX2-1, and a 3-1th pixel PX3-1. For example, a pixel electrode 300 may include a 1-1th pixel electrode 311 disposed in the 1-1th pixel PX1-1, a 2-1th pixel electrode 321 disposed in the 2-1th pixel PX2-1, and a 3-1th pixel electrode 331 disposed in the 3-1 th pixel PX3-1. The 1-1th pixel PX1-1, the 2-1th pixel PX2-1, and the 3-1th pixel PX3-1 may emit light of different wavelength bands. For example, the 1-1th pixel PX1-1 may emit red light, the 2-1th pixel PX2-1 may emit green light, and the 3-1th pixel PX3-1 may emit blue light. According to an embodiment, a plurality of exposed upper surfaces A, which are portions of the pixel electrode 300 exposed by a pixel-defining layer 150, may include a 1-1th exposed upper surface A1-1 disposed on the 1-1th pixel electrode 311, a 2-1th exposed upper surface A2-1 disposed on the 2-1th pixel electrode 321, and a 3-1th exposed upper surface A3-1 disposed on the 3-1th pixel electrode 331. For example, an area (or size) of the 1-1th exposed upper surface A1-1 may be different from an area (or size) of the 2-1th exposed upper surface A2-1 or an area (or size) of the 3-1th exposed upper surface A3-1.

The area (or size) of the 1-1th exposed upper surface A1-1 may be larger than the area (or size) of the 2-1th exposed upper surface A2-1 and the area (or size) of the 3-1th exposed upper surface A3-1. The area (or size) of the 2-1th exposed upper surface A2-1 may be larger than the area (or size) of the 1-1th exposed upper surface A1-1 and the area (or size) of the 3-1th exposed upper surface A3-1. The area (or size) of the 3-1th exposed upper surface A3-1 may be larger than the area (or size) of the 1-1th exposed upper surface A1-1 and the area (or size) of the 2-1th exposed upper surface A2-1.

For example, the areas of the plurality of exposed upper surfaces A may be varied or modified.

For example, the shapes of the plurality of exposed upper surfaces A may include various shapes such as a square, a circle, and the like, by a pixel-defining layer. Referring to FIG. 2, the exposed upper surfaces disposed in the pixels PX emitting light of the same wavelength band are all illustrated to have the same exposed upper surface, but the disclosure is not limited thereto.

Referring to FIG. 3, the pixel PX may include the 1-1th pixel PX1-1, the 1-2th pixel PX1-2, the 1-3th pixel PX1-3, the 2-1th pixel PX2-1, a 2-3th pixel PX2-3, and the 3-1th pixel PX3-1. For example, the pixel electrode 300 may include the 1-1th pixel electrode 311 disposed in the 1-1th pixel PX1-1, the 1-2th pixel electrode 312 disposed in the 1-2th pixel PX1-2, the 1-3th pixel electrode 313 disposed in the 1-3th pixel PX1-3, the 2-1th pixel electrode 321 disposed in the 2-1th pixel PX2-1, a 2-3th pixel electrode 323 (including a 2-3th exposed upper surface A2-3) disposed in the 2-3th pixel PX2-3, and the 3-1th pixel electrode 331 disposed in the 3-1th pixel PX3-1.

In the embodiment, the areas of the plurality of exposed upper surfaces A disposed in the pixels PX emitting light of the same wavelength band may not be the same.

In an embodiment, the 1-1th exposed upper surface A1-1 on the 1-1th pixel electrode 311 may be larger than the 1-2th exposed upper surface A1-2 on the 1-2th pixel electrode 312. The 1-2th exposed upper surface A1-2 may be larger than the 1-3th exposed upper surface A1-3 on the 1-3th pixel electrode 313. The area of the plurality of exposed upper surfaces A may randomly include the area of the 1-1th exposed upper surface A1-1, the area of the 1-2th exposed upper surface A1-2, or the area of the 1-3th exposed upper surface A1-3.

The above descriptions may be applied not only to the pixel PX emitting red light but also to the pixels PX emitting green light or blue light.

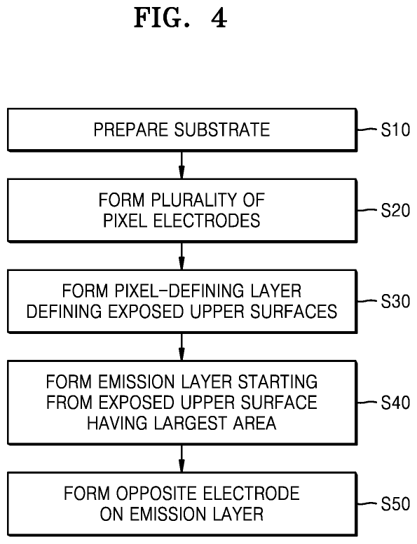

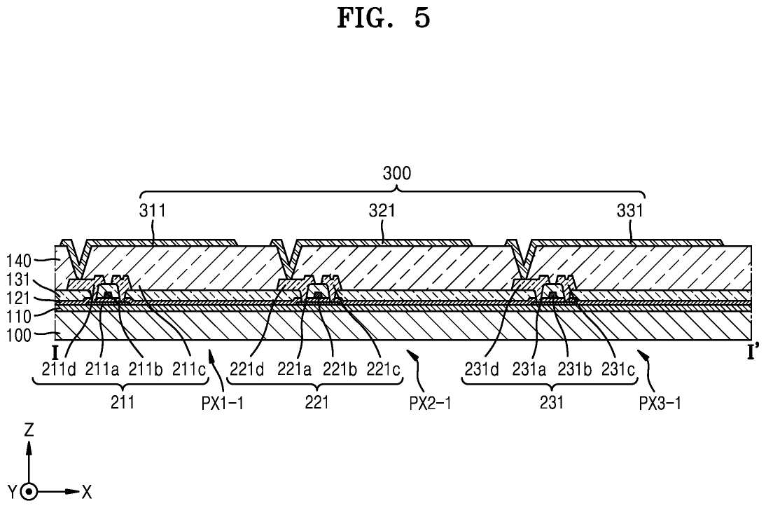

FIG. 4 is a flowchart of a method of manufacturing a display device 1, according to an embodiment. FIGS. 5 to 11 are schematic cross-sectional views illustrating, in sequence, a method of manufacturing a display device.

Referring to FIG. 4, an embodiment may include various processes, e.g., preparing a substrate (S10), forming a plurality of pixel electrodes (S20), forming a pixel-defining layer defining an exposed upper surface (S30), forming an emission layer on an exposed upper surface having a relatively large area earlier, and forming an emission layer on an exposed upper surface having a relatively small area later (S40), and forming an opposite electrode on the emission layer (S50).

Referring to FIG. 5, a substrate 100 may be prepared in the process S10.

The substrate 100 may include glass, metal, or polymer resin. In case that the substrate 100 has flexible or bendable properties, the substrate 100 may include a polymer resin, for example, polyethersulphone, polyacrylate, polyetherimide, polyether imide, polyethylene naphthalate, polyethylene terephthalate, polyphenylene sulfide, polyarylate, polyimide, polycarbonate or cellulose acetate propionate. Various modifications may be made to the substrate 100. For example, the substrate 100 may have a multi-layer structure including two layers each including a polymer resin as described above and a barrier layer that is arranged between the two layers and includes an inorganic material such as silicon oxide, silicon nitride, silicon oxynitride, etc.

Organic light-emitting elements may be disposed on the substrate 100. 1-1th, 2-1th, and 3-1th thin-film transistors 211, 221, and 231 may be disposed on the substrate 100, in addition to the organic light-emitting elements. The 1-1th, 2-1th, and 3-1th thin-film transistors 211, 221, and 231 may be electrically connected to the organic light-emitting elements. For example, the 1-1th, 2-1th, and 3-1th thin-film transistors 211, 221 and 231 may be electrically connected to the 1-1th, 2-1th, and 3-1th pixel electrodes 311, 321 and 331 of the organic light-emitting elements.

Hereinafter, the 1-1th thin-film transistor 211 will be described for convenience of description, and the description thereof may be applied to the 2-1th thin-film transistor 221 including a 2-1th semiconductor layer 221a, a 2-1th gate electrode 221b, a 2-1th source electrode 221c, and a 2-1th drain electrode 221d and the 3-1th thin-film transistor 231 including a 3-1th semiconductor layer 231a, a 3-1th gate electrode 231b, a 3-1th source electrode 231c, and a 3-1th drain electrode 231d. A description of components of the 2-1th thin-film transistor 221 and the 3-1th thin-film transistor 231 will be omitted for convenience of description.

The 1-1th thin-film transistor 211 may include a 1-1th semiconductor layer 211a, a 1-1th gate electrode 211b, a 1-1th source electrode 211c, and a 1-1th drain electrode 211d. For example, the 1-1th semiconductor layer 211a may include amorphous silicon, polycrystalline silicon or an organic semiconductor material. The 1-1th gate electrode 211b may include various conductive materials and have various layered structures, and may include, for example, a Mo layer and an Al layer. The 1-1th source electrode 211c and the 1-1th drain electrode 211d may include various conductive materials and have various layered structures. For example, the 1-1th source electrode 211c and the 1-1th drain electrode 211d may include a Ti layer and an Al layer.

For example, a gate insulating layer 121 including an inorganic material such as silicon oxide, silicon nitride, and/or silicon oxynitride may be between the 1-1th semiconductor layer 211a and the 1-1th gate electrode 211b to ensure insulation between the 1-1th semiconductor layer 211a and the 1-1th gate electrode 211b. For example, an interlayer insulating layer 131 including an inorganic material such as silicon nitride, silicon oxynitride, silicon oxide, titanium oxide or aluminum oxide may be disposed on the 1-1th gate electrode 211b. The 1-1th source electrode 211c and the 1-1th drain electrode 211d may be disposed above the interlayer insulating layer 131. As described above, an insulating layer including an inorganic material may be formed by a chemical vapor deposition (CVD) process or an atomic layer deposition (ALD) process. The processes may be applied to other embodiments and modifications thereof to be described below.

A buffer layer 110 including at least one of a silicon nitride layer, a silicon oxynitride layer, a silicon oxide layer, a titanium oxide layer, and an aluminum oxide layer may be between the 1-1th thin-film transistor 211 and the substrate 100. The buffer layer 110 may increase the smoothness of an upper surface of the substrate 100 or may prevent or minimize penetration of impurities from the substrate 100 or the like into the 1-1th semiconductor layer 211a of the 1-1th thin-film transistor 211.

A planarization layer 140 may be disposed on the 1-1th thin-film transistor 211. In case that an organic light-emitting element is disposed on the 1-1th thin-film transistor 211, the planarization layer 140 may have a function of substantially planarizing an upper portion of a protective layer covering the 1-1th thin-film transistor 211. The planarization layer 140 may include an organic material such as acrylic resin, epoxy resin, phenolic resin, polyamide resin, polyimide resin, benzocyclobutene (BCB), or hexamethyldisiloxane (HMDSO), and the like. The planarization layer 140 is illustrated as a single layer in FIG. 5. In another example, the planarization layer 140 may include multiple layers. As such, various modifications may be made thereto.

For example, the pixel electrode 300 may be formed on the substrate 100 in the process S20.

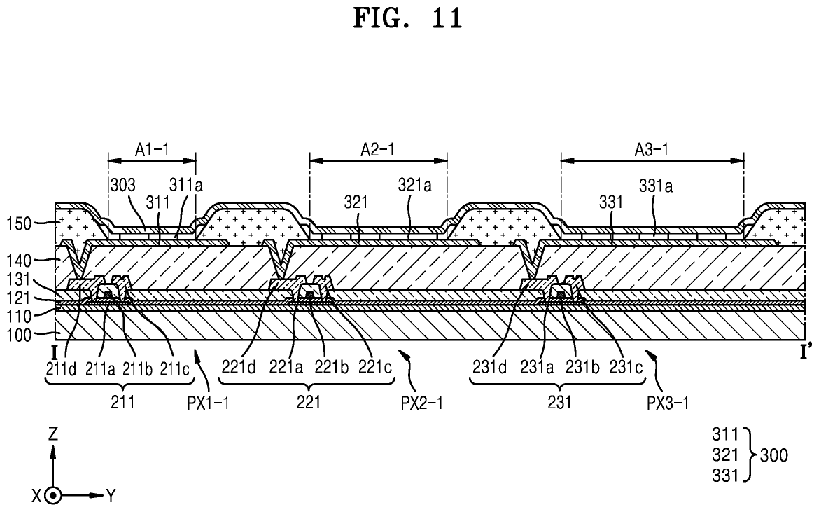

In case that the display device 1 is implemented as a top emission type display device that emits light to the outside through an opposite electrode 303 (see FIG. 11), the pixel electrode 300 may include a metal material having a high reflectance, such as a stacked structure of aluminum and titanium (Ti/Al/Ti), a stacked structure of aluminum and ITO (ITO/Al/ITO), a stacked structure of silver and ITO (ITO/Ag/ITO), an APC alloy, and a stacked structure of an APC alloy and ITO (ITO/APC/ITO). APC alloys may include alloys of silver (Ag), palladium (Pd), and/or copper (Cu).

In case that the display device 1 is implemented as a bottom emission type display device that emits light to the outside through the pixel electrode 300, the pixel electrode 300 may include a transparent conductive material (TCO) such as ITO or IZO, which transmits light, or a semi-transmissive conductive material such as magnesium (Mg), silver (Ag), or an alloy of magnesium (Mg) and silver (Ag).

FIG. 5 schematically shows a portion of each of three pixels of a display device for convenience of description. However, embodiments are not limited thereto. For example, components of thin-film transistors may not be disposed in a same zx plane. For example, the 1-1th gate electrode 211b, the 1-1th source electrode 211c, and the 1-1th drain electrode 211d of the 1-1th thin-film transistor 211 may not be disposed in the same zx plane. Other various modifications may be made. For example, in any one zx plane, only the 1-1th gate electrode 211b and the 1-1th source electrode 211c may be viewed and the 1-1th drain electrode 211d may not be viewed.

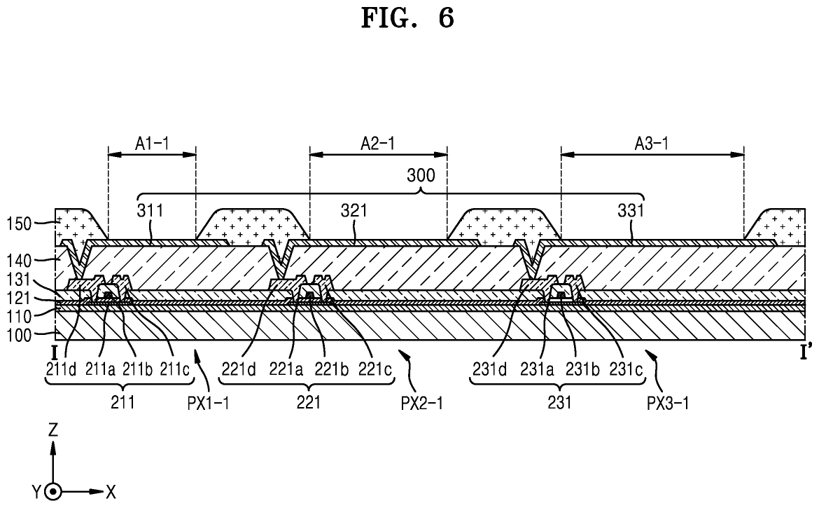

Referring to FIG. 6, the pixel-defining layer 150 defining an exposed upper surface A of the pixel electrode 300 may be formed in the process S30.

The pixel-defining layer 150 may be formed through an exposure process and a developing process by using a mask after applying a material for forming the pixel-defining layer 150. The pixel-defining layer 150 may be disposed on the planarization layer 140. The pixel-defining layer 150 may have openings respectively corresponding to sub-pixels to thus have a function of defining pixels.

For example, the pixel-defining layer 150 may cover edge portions of the 1-1th pixel electrode 311, edge portions of the 2-1th pixel electrode 321, and edge portions of the 3-1th pixel electrode 331, or the like to define the 1-1th exposed upper surface A1-1 including a central upper surface of the 1-1th pixel electrode 311, the 2-1th exposed upper surface A2—including a central upper surface of the 2-1th pixel electrode 321, and the 3-1th exposed upper surface A3-1 including a central upper surface of the 3-1th pixel electrode 331. The pixel-defining layer 150 may define varying areas of the plurality of exposed upper surfaces A that differ from each other, as described above. For example, the shapes of the plurality of exposed upper surfaces A may be defined in various manners.

FIG. 6 illustrates that the 3-1th exposed upper surface A3-1 has the largest area, and the 1-1th exposed upper surface A1-1 has a smallest area. However, the areas of the plurality of exposed upper surfaces A are not limited thereto. For example, the areas (or sizes) of the plurality of exposed upper areas A may be different from the illustration of FIG. 6.

The pixel-defining layer 150 may increase a distance between the edge portions of the 1-1th pixel electrode 311, or the like and the opposite electrode 303 (see FIG. 11) above the 1-1th pixel electrode 311, or the like, thereby preventing an arc (or a short circuit) from occurring at the edge portions of the 1-1th pixel electrode 311 or the like. The pixel-defining layer 150 as described above may include, for example, an organic material such as acrylic resin, epoxy resin, phenolic resin, polyamide resin, polyimide resin, HMDSO, or the like.

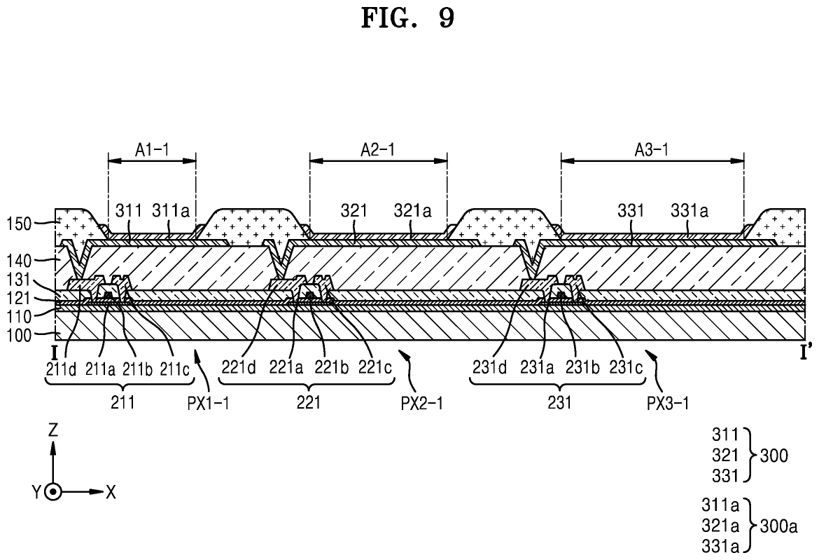

In an embodiment, an upper surface or a side surface of the pixel-defining layer 150 may have liquid repellency. In the descriptions, liquid repellency refers to a relatively large contact angle with respect to an ink containing a solvent or an organic material, which is included in an ink forming an emission layer 300a (see FIG. 9) during an inkjet process. As the upper surface of the pixel-defining layer 150 has liquid repellency, the application (or deposition) of ink to a non-emissive area during the inkjet process may be prevented or minimized. The pixel-defining layer 150 may include a fluororesin. For example, the pixel-defining layer 150 may include an organic material having an unsaturated bond and a fluoro group. In another example, the pixel-defining layer 150 may include an organic material having an unsaturated bond and fluorine. A fluoro group or fluorine included in a surface of the pixel-defining layer 150 may improve the liquid-repellant properties of the upper surface of the pixel-defining layer 150.

In an embodiment, after the process of forming of the pixel-defining layer 150, a process of baking the pixel-defining layer 150 may be performed. In the process of baking the pixel-defining layer 150, a liquid-repellent material or a hydrophobic material included in the pixel-defining layer 150 may float (or be filled) to the upper surface of the pixel-defining layer 150. Accordingly, the upper surface of the pixel-defining layer 150 may have liquid repellency, and the side surface of the pixel-defining layer 150 may not have liquid repellency.

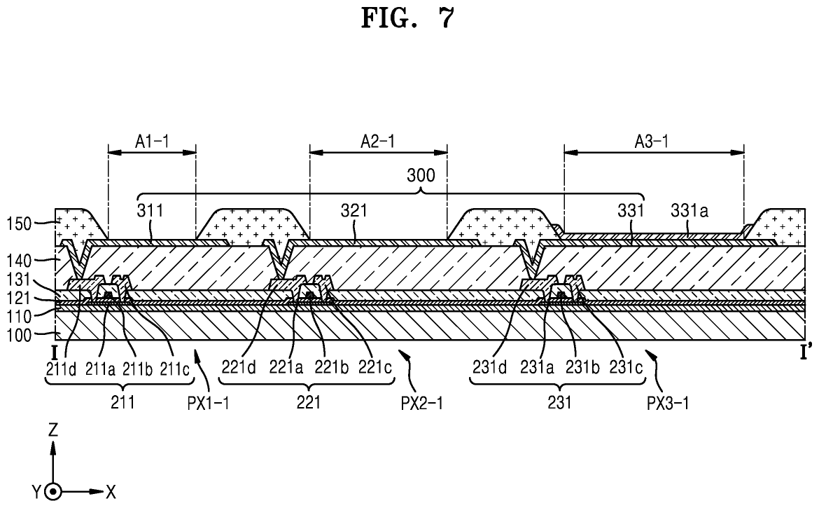

For example, an emission layer may be sequentially formed on the plurality of pixel electrodes 300 in the order from an exposed upper surface having the largest area to an exposed upper surface having the smallest area as illustrated in FIGS. 7 to 9 in the process S40. FIGS. 7 to 9 each illustrate a portion of a schematic cross-sectional view taken along line I-I′ of FIG. 2.

A method of manufacturing a display device according to an embodiment may include: preparing the substrate 100; forming the plurality of pixel electrodes 300 on the substrate 100; forming the pixel-defining layer 150 covering edge portions of the plurality of pixel electrodes 300 and defining the plurality of exposed upper surfaces A including a central upper surface of the plurality of pixel electrodes 300; and forming the emission layer 300a on the plurality of pixel electrodes 300. In the forming of the emission layer 300a, the emission layer 300a may be formed by ejecting ink onto the plurality of exposed upper surfaces A in the order from an exposed upper surface A having the largest area to an exposed upper surface A having the smallest area.

In an embodiment, the pixel electrodes 300 may include the 1-1th pixel electrode 311 disposed in the 1-1th pixel PX1-1, the 2-1th pixel electrode 321 disposed in the 2-1th pixel PX2-1, and the 3-1th pixel electrode 331 disposed in the 3-1th pixel PX3-1. The 1-1th pixel PX1-1, the 2-1th pixel PX2-1, and the 3-1th pixel PX3-1 may emit light of different wavelength bands, respectively. The 1-1th pixel PX1-1 may emit red light, the 2-1th pixel PX2-1 may emit green light, and the 3-1th pixel PX3-1 may emit blue light. The area (or size) of the 1-1th exposed upper surface A1-1 may be different from the area (or size) of the 2-1th exposed upper surface A2-1 or the area (or size) of the 3-1th exposed upper surface A3-1.

The 1-1th emission layer 311a may be disposed on the 1-1th pixel electrode 311, the 2-1th emission layer 321a may be disposed on the 2-1th pixel electrode 321, and the 3-1th emission layer 331a may be disposed on the 3-1th pixel electrode 331. The emission layer 300a may be formed by an inkjet printing method. For example, the 1-1th emission layer 311a, the 2-1th emission layer 321a, and the 3-1th emission layer 331a may be formed by depositing a material for forming an emission layer, by using an inkjet printing method, on the 1-1th exposed upper surface A1-1 of the 1-1th pixel electrode 311, which is exposed by the pixel-defining layer 150, the 2-1th exposed upper surface of the 2-1th pixel electrode 321, which is exposed by the pixel-defining layer 150, and the 3-1th exposed upper surface A3-1 of the 3-1th pixel electrode 331, which is exposed by the pixel-defining layer 150.

In the forming of the emission layer 300a by an inkjet printing method, ink first ejected onto a certain pixel electrode 300 may be naturally dried while ink is ejected onto the pixel electrode 300 next in order. Compared with a drying process, which may be controlled to dry uniformly through process conditions, drying conditions of natural drying may not be controlled and may cause non-uniformity of the ink. Accordingly, there is a problem that an unintended difference in thickness occurs in each portion within an area onto which ink is ejected. According to the method of manufacturing a display device 1, according to the embodiment, natural drying that causes such a problem may be minimized.

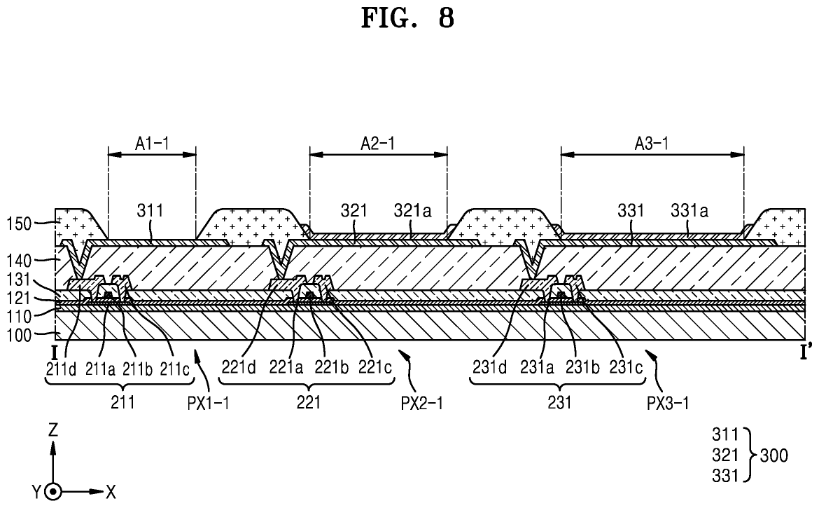

For example, referring to FIG. 2, the area (or size) of the 3-1th exposed upper surface A3-1 may be the largest and the area (or size) of the 1-1th exposed upper surface A1-1 may be the smallest. In this case, referring to FIG. 7, the 3-1th emission layer 331a may be formed by first ejecting ink onto the 3-1th exposed upper surface A3-1. Referring to FIG. 8, ink may be ejected onto the 2-1th exposed upper surface A2-1 to form the 2-1th emission layer 321a. Referring to FIG. 9, ink is ejected onto the 1-1th exposed upper surface A1-1 to form the 1-1th emission layer 311a. For example, the emission layer 300a may be formed by ejecting ink onto the plurality of exposed upper surfaces A in the order from the exposed upper surface A having the largest area to the exposed upper surface A having the smallest area.

In the 3-1th exposed upper surface A3-1 which has a relatively large area, a relatively large amount of ink may be filled therein, and thus the 3-1th exposed upper surface A3-1 may be relatively less affected by natural drying. For example, by ejecting ink in the order of the 2-1th exposed upper surface A2-1 and the 1-1th exposed upper surface A1-1, drying of ink ejected to a narrow portion may be reduced by an amount of ink that is ejected earlier to a relatively large area and dried. For example, as ink is ejected later (or ejected to the narrow portion), the natural drying time may be reduced.

For example, problems caused by natural drying may be minimized by ejecting ink to a narrow area that is relatively much affected by natural drying after ejecting ink to a large area that is relatively less affected by natural drying.

In another example, the area (or size) of the 1-1th exposed upper surface A1-1 may be larger than the area (or size) of the 2-1th exposed upper surface A2-1 and the area (or size) of the 3-1th exposed upper surface A3-1. In another example, the area (or size) of the 2-1th exposed upper surface A2-1 may be larger than the area (or size) of the 1-1th exposed upper surface A1-1 and the area (or size) of the 3-1th exposed upper surface A3-1. For example, the areas (or sizes) of the plurality of exposed upper surfaces A may be varied or modified.

In an embodiment, in case that natural drying is minimized by ejecting ink onto the plurality of exposed upper surfaces A in the order from the exposed upper surface having the largest area to the exposed upper surface A having the smallest area, a flat upper portion of the emission layer 300a at a center portion of each of the exposed upper surfaces A1-1, A2-1, and A3-1 may be formed. In another example, a flat upper portion of the emission layer 300a at edge portions of each of the exposed upper surfaces A1-1, A2-1, and A3-1 may be formed. This is because a thickness difference due to natural drying may be minimized.

For example, the emission layer 300a may be disposed on the 1-1th pixel electrode 311 to the 3-1th pixel electrode 331. For example, a hole injection layer (HIL) or a hole transport layer (HTL) may be between the pixel electrode 300 and the emission layer 300a. For example, an electron transport layer (ETL) or an electron injection layer (EIL) may be disposed on the emission layer 300a. The HIL, the HTL, the ETL, and/or the EIL may be integral with each other on the plurality of pixel electrodes 300. In another example, the HIL, the HTL, the ETL, and/or the EIL may be a layer patterned to correspond to each of the pixel electrodes 300. The HIL, the HTL, the ETL, and/or the EIL may be formed by a vapor deposition method, a screen printing method, a laser thermal transfer method, an inkjet printing method, or the like.

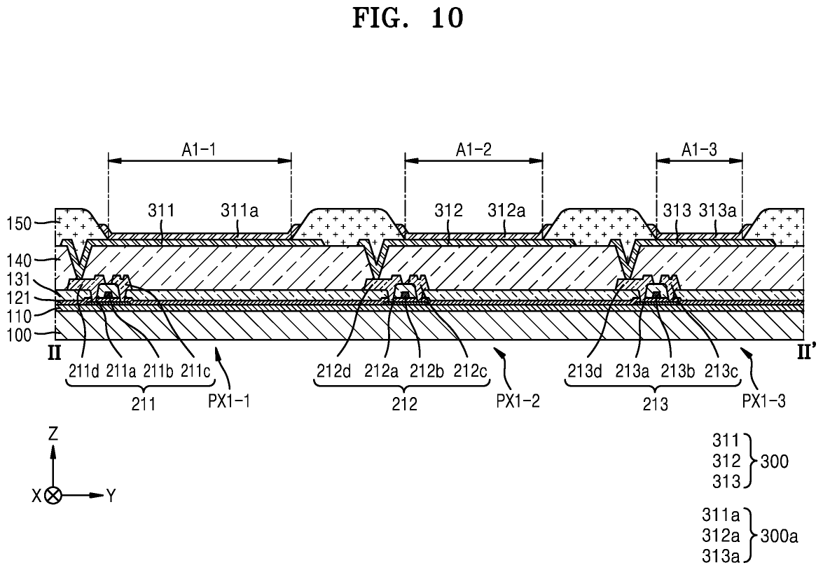

FIG. 10 is a portion of a schematic cross-sectional view taken along line II-II″ of FIG. 3. A method of manufacturing a display device 1 according to an embodiment may include: preparing the substrate 100; forming, on the substrate 100, the plurality of pixel electrodes 300 disposed in the plurality of pixels PX emitting light of a same wavelength band; forming the pixel-defining layer 150 covering edge portions of the plurality of pixel electrodes 300 and defining the plurality of exposed upper surfaces A including a central upper surface of the plurality of pixel electrodes 300, such that respective areas of the plurality of exposed upper surfaces A are different from each other; and forming the emission layer 300a on the plurality of pixel electrodes 300. For example, in the forming of the emission layer 300a, the emission layer 300a may be formed by ejecting ink onto the plurality of exposed upper surfaces A in the order from an exposed upper surface A having the largest area to an exposed upper surface A having the smallest area. For example, the display device 1 may include 1-1th, 1-2th, and 1-3th thin-film transistors 211, 212, and 213 may be disposed on the substrate 100. The 1-1th thin-film transistor 211 may include a 1-1th semiconductor layer 211a, a 1-1th gate electrode 211b, a 1-1th source electrode 211c, and a 1-1th drain electrode 211d. The 1-2th thin-film transistor 212 may include a 1-2th semiconductor layer 212a, a 1-2th gate electrode 212b, a 1-2th source electrode 212c, and a 1-2th drain electrode 212d. The 1-3th thin-film transistor 213 may include a 1-3th semiconductor layer 213a, a 1-3th gate electrode 213b, a 1-3th source electrode 213c, and a 1-3th drain electrode 213d.

In an embodiment, the plurality of pixels PX emitting light of a same wavelength band may emit any one of red light, green light, and blue light.

In an embodiment, the pixel electrodes 300 may include the 1-1th pixel electrode 311 disposed in the 1-1th pixel PX1-1, the 1-2th pixel electrode 312 disposed in the 1-2th pixel PX1-2, and the 1-3th pixel electrode 313 disposed in the 1-3th pixel PX1-3.

In an embodiment, the 1-1th exposed upper surface A1-1 on the 1-1th pixel electrode 311 may be larger than the 1-2th exposed upper surface A1-2 on the 1-2th pixel electrode 312. The 1-2th exposed upper surface A1-2 may be larger than the 1-3th exposed upper surface A1-3 on the 1-3th pixel electrode 313.

Referring to FIG. 10, in case that the area (or size) of the 1-1th exposed upper surface A1-1 is largest and the area (or size) of the 1-3th exposed upper surface A1-3 is smallest, the formation order of the emission layer 300a may be in the order of the 1-1th emission layer 311a, the 1-2th emission layer 312a, and the 1-3th emission layer 313a.

The area (or size) of the plurality of exposed upper surfaces A may randomly include the area (or size) of the 1-1th exposed upper surface A1-1, the area (or size) of the 1-2th exposed upper surface A1-2, or the area (or size) of the 1-3th exposed upper surface A1-3. For example, the emission layer may be formed by ejecting the ink onto the plurality of exposed upper surfaces A in the order from the exposed upper surface A having the largest area to the exposed upper surface A having the smallest area.

As described above, problems caused by natural drying may be minimized by ejecting ink onto a narrow area that is relatively much affected by natural drying after ejecting ink onto a large area that is relatively less affected by natural drying.

Referring to FIG. 11, an opposite electrode 303 may be formed on the emission layer 300a in the process S50.

A method of manufacturing a display device 1 according to an embodiment, may include: preparing the substrate 100; forming the plurality of pixel electrodes 300 on the substrate 100; forming the pixel-defining layer 150 covering edge portions of the plurality of pixel electrodes 300 and defining the plurality of exposed upper surfaces A including a central upper surface of the plurality of pixel electrodes 300; and forming the emission layer 300a on the plurality of pixel electrodes 300. For example, in the forming of the emission layer 300a, the emission layer 300a may be formed by ejecting ink onto the plurality of exposed upper surfaces A in the order from the exposed upper surface A having the largest area to the exposed upper surface A having the smallest area. In an embodiment, the method may further include forming the opposite electrode 303 on the emission layer 300a. The opposite electrode 303 may cover the emission layer 300a and the pixel-defining layer 150.

The opposite electrode 303 may be disposed to cover the display area DA. For example, the opposite electrode 303 may be integral with each other formed in a plurality of organic light-emitting elements to correspond to the plurality of pixel electrodes 300.

The opposite electrode 303 may cover the display area DA and may extend to the peripheral area NDA outside the display area DA. Accordingly, the opposite electrode 303 may be electrically connected to an electrode power supply line disposed in the peripheral area NDA. In case that the display device 1 is implemented as a top emission type display device, the opposite electrode 303 may be formed of a transparent conductive material (TCO) such as ITO or IZO that transmit light, or a semi-transmissive conductive material such as magnesium (Mg), silver (Ag), or an alloy of magnesium (Mg) and silver (Ag).

In case that case that the display device 1 is implemented as a bottom emission type display device, the opposite electrode 303 may include a metal material having a high reflectance, such as a stacked structure of aluminum and titanium (Ti/Al/Ti), a stacked structure of aluminum and ITO (ITO/Al/ITO), an APC alloy, and a stacked structure of an APC alloy and ITO (ITO/APC/ITO). APC alloys include alloys of silver (Ag), palladium (Pd) and/or copper (Cu).

Since the organic light-emitting elements are easily damaged by moisture or oxygen from the outside, an encapsulation layer may cover the organic light-emitting elements to protect them. The encapsulation layer may cover the display area DA and may extend to at least a portion of the peripheral area NDA. The encapsulation layer may include a first inorganic encapsulation layer, an organic encapsulation layer, and a second inorganic encapsulation layer.

The first inorganic encapsulation layer and the second inorganic encapsulation layer may include silicon nitride, silicon oxynitride, silicon oxide, titanium oxide, or aluminum oxide. The organic encapsulation layer may include an acrylic resin, an epoxy resin, a phenolic resin, a polyamide resin, or a polyimide resin.

As described above, according to the method of manufacturing a display device, according to an embodiment, by ejecting ink onto a pixel electrode in the order from a relatively large area to a relatively small area of the pixel electrode, a degree of natural drying of ink may be minimized and a high-quality image may be displayed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a display device, the method comprising:
preparing a substrate;
forming a plurality of pixel electrodes on the substrate;
forming a pixel-defining layer covering edge portions of the plurality of pixel electrodes and defining a plurality of exposed upper surfaces of the plurality of pixel electrodes; and
forming an emission layer on the plurality of exposed upper surfaces of the plurality of pixel electrodes,
wherein the forming of the emission layer comprises forming the emission layer by ejecting ink onto the plurality of exposed upper surfaces in an order from an exposed upper surface having a largest area to an exposed upper surface having a smallest area.

2. The method of claim 1, wherein
the plurality of pixel electrodes comprise:
a 1-1th pixel electrode disposed in a 1-1th pixel,
a 2-1 th pixel electrode disposed in a 2-1th pixel, and
a 3-1th pixel electrode disposed in a 3-1th pixel, and
the 1-1th pixel, the 2-1th pixel, and the 3-1th pixel are configured to emit light of different wavelength bands from each other.

3. The method of claim 2, wherein
the 1-1th pixel is configured to emit red light,
the 2-1th pixel is configured to emit green light, and
the 3-1th pixel is configured to emit blue light.

4. The method of claim 3, wherein
the plurality of exposed upper surfaces comprise:
a 1-1th exposed upper surface disposed on the 1-1th pixel electrode,
a 2-1th exposed upper surface disposed on the 2-1th pixel electrode, and
a 3-1th exposed upper surface disposed on the 3-1th pixel electrode, and
an area of the 1-1th exposed upper surface is different from an area of the 2-1th exposed upper surface or an area of the 3-1th exposed upper surface.

5. The method of claim 4, wherein the area of the 1-1th exposed upper surface is larger than the area of the 2-1th exposed upper surface and the area of the 3-1th exposed upper surface.

6. The method of claim 4, wherein the area of the 2-1th exposed upper surface is larger than the area of the 1-1th exposed upper surface and the area of the 3-1th exposed upper surface.

7. The method of claim 4, wherein the area of the 3-1th exposed upper surface is larger than the area of the 1-1th exposed upper surface and the area of the 2-1th exposed upper surface.

8. The method of claim 1, wherein the forming of the emission layer comprises forming the emission layer including an upper portion of the emission layer that is flat at a center portion of each of the plurality of exposed upper surfaces.

9. The method of claim 1, further comprising baking the pixel-defining layer after the forming of the pixel-defining layer.

10. The method of claim 1, wherein an upper surface of a side surface of the pixel-defining layer has liquid repellency.

11. The method of claim 1, further comprising forming an opposite electrode on the emission layer.

12. The method of claim 11, wherein the opposite electrode covers the emission layer and the pixel-defining layer.

13. A method of manufacturing a display device, the method comprising:
preparing a substrate;
forming, on the substrate, a plurality of pixel electrodes disposed in a plurality of pixels emitting light of a same wavelength band;
forming a pixel-defining layer covering edge portions of the plurality of pixel electrodes and defining a plurality of exposed upper surfaces of the plurality of pixel electrodes, the plurality of exposed upper surfaces having different areas from each other; and
forming an emission layer on the plurality of exposed upper surfaces of the plurality of pixel electrodes,
wherein the forming of the emission layer comprises forming the emission layer by ejecting ink onto the plurality of exposed upper surfaces in an order from an exposed upper surface having a largest area to an exposed upper surface having a smallest area.

14. The method of claim 13, wherein
the plurality of pixel electrodes comprise:
a 1-1th pixel electrode disposed in a 1-1th pixel, and
a 1-2th pixel electrode disposed in a 1-2th pixel, and
a 1-1th exposed upper surface on the 1-1th pixel electrode is larger than a 1-2th exposed upper surface on the 1-2th pixel electrode.

15. The method of claim 14, wherein
the plurality of pixel electrodes further comprise a 1-3th pixel electrode disposed in a 1-3th pixel, and
the 1-2th exposed upper surface is larger than a 1-3th exposed upper surface on the 1-3th pixel electrode.

16. The method of claim 15, wherein areas of the plurality of exposed upper surfaces comprise an area of the 1-1th exposed upper surface, an area of the 1-2th exposed upper surface, and an area of the 1-3th exposed upper surface, which are randomly arranged.

17. The method of claim 13, wherein the plurality of pixels emitting light of a same wavelength band are configured to emit one of red light, green light, and blue light.

18. The method of claim 13, further comprising baking the pixel-defining layer after the forming of the pixel-defining layer.

19. The method of claim 13, wherein an upper surface of a side surface of the pixel-defining layer has liquid repellency.

20. The method of claim 13, further comprising forming an opposite electrode on the emission layer.
